(19) United States
(12) Patent Application Publication
(10) Pub. No.: US 2006/0045667 A1
(43) Pub. Date: Mar. 2, 2006

(54) Substrate handling system and process for manufacturing large substrates

(76) Inventor: Stephen E. Savas, San Jose, CA (US)

Correspondence Address: EDWARD S. WRIGHT, 1100 ALMA STREET, SUITE 207, MENLO PARK, CA, 94025, US

(21) Appl. No.: 11/180,970

(22) Filed: Jul. 13, 2005

Related U.S. Application Data
(60) Provisional application No. 60/588,260, filed on Jul. 14, 2004.

(51) Int. Cl. H01L 21/677

(52) U.S. Cl. 414/217

(57) ABSTRACT

Air floatation system and method for simultaneously moving very large substrates into and out of a load locked chamber for vacuum processing. While the substrates are being processed, input and output load locks are cycling to atmospheric pressure and back to vacuum for loading and unloading the substrates. Following loading or unloading, valves between all chambers are opened and the substrates are moved in vacuum, nearly simultaneously and in line from load lock to process chambers and from the process chambers to output load lock. This minimizes both the total process time per substrate and the cost and size of the handling system. It permits the use of valves of minimum size and cost, minimizes the cost of the handling mechanism, prevents the handling time from adding to total process time, and the loading and unloading system is flexible for both in-line and side-loading configurations.

### BACKGROUND OF THE INVENTION

1. Field of Invention

This invention pertains generally to the manufacture of substrates and, more particularly, to a substrate handling system and process for manufacturing large substrates.

2. Related Art

Handling and processing very large sheets of glass rapidly and in a low-cost system is important in reducing panel cost for mass-market availability of large screen televisions or displays. This is particularly true for competitive vacuum-based processes such as photoresist stripping, chemical vapor deposition, or etching systems for manufacturing large flat panel displays.

### OBJECTS AND SUMMARY OF THE INVENTION

It is, in general, an object of the invention to provide a new and improved substrate handling system and process for use in the manufacture of large substrates.

Another object of the invention is to provide a system and process of the above character in which the size of the system and the cost of substrate handling are minimized and substrate productivity is maximized.

These and other objects are achieved in accordance with the invention by moving a substrate to be processed into a supplying load lock chamber where it is heated to become much closer to the processing temperature as it is kept at a controlled distance from the heater surface within the load lock, maintaining the supplying load lock chamber at a transfer pressure that is below the processing pressure as the substrate is being heated, moving the substrate from the supplying load lock onto a pedestal in a processing chamber, with the substrate being supported all or in part by the flow of gas from the pedestal beneath the substrate and arriving into the processing chamber at a temperature much closer to the desired temperature for processing, and moving the substrate into a separate receiving load lock, with the substrate being supported all or in part by the flow of gas from the pedestal beneath the substrate. The substrate is moved into the processing chamber substantially at the same time as a previously processed substrate is moved into the receiving load lock chamber, and the substrate is cooled down in the receiving load lock chamber as that chamber is being repressurized to atmospheric pressure.

### BRIEF DESCRIPTION OF THE DRAWINGS

FIG. 1 is a cross-sectional view, partly schematic, of one embodiment of a dry stripping system incorporating the invention.

FIG. 2 is a top plan view, partly schematic, of another embodiment of a dry stripping system incorporating the invention.

FIG. 3 is a cross-sectional view, partly schematic, of a load lock or processing chamber incorporating the invention.

### DETAILED DESCRIPTION

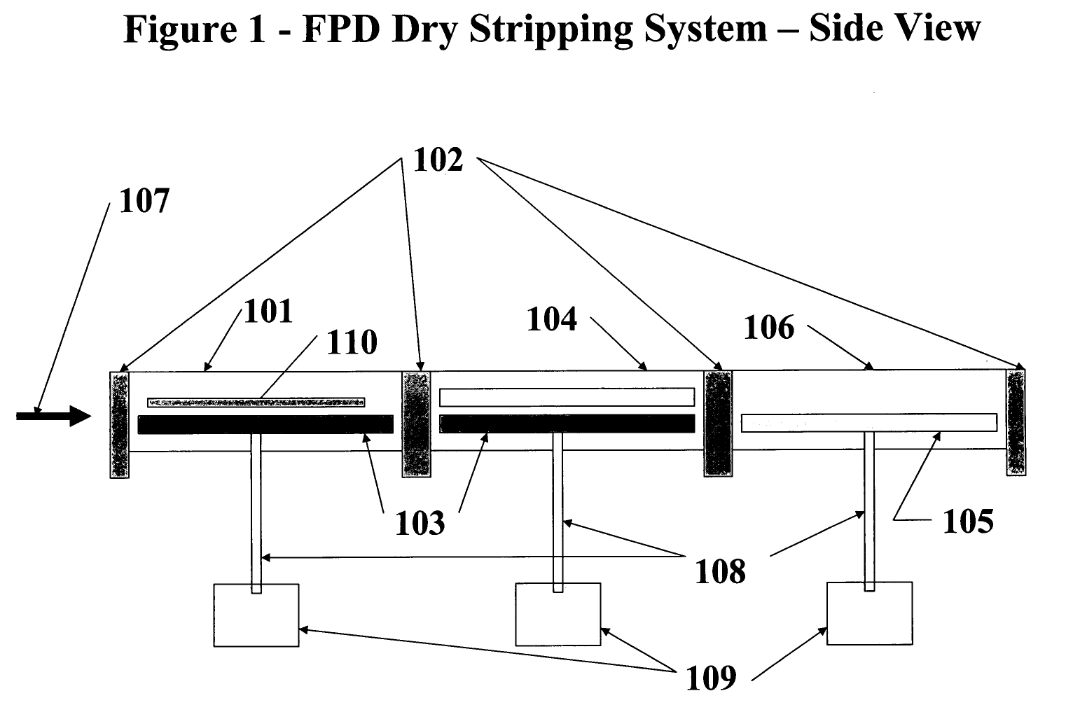

The processing system shown in FIG. 1 has an input load lock 101, a single processing chamber 104, and an output or output load lock 106. Vacuum valves 102 are positioned in line with the load locks and the processing chamber and can be opened to pass a substrate moving in the direction indicated by arrow 107. A substrate 110 is shown in a levitated position on a pedestal 103 in the chamber of input load lock 101, as it might, for example, be during a pumpdown step in which substrate heat-up might take place. A cool-down pedestal 105 is provided in the output load lock. Gas for levitation or floatation of the substrates is provided by gas lines 108 and controllers 109, with a separate line and controller being provided for the processing chamber and each of the two load lock chambers.

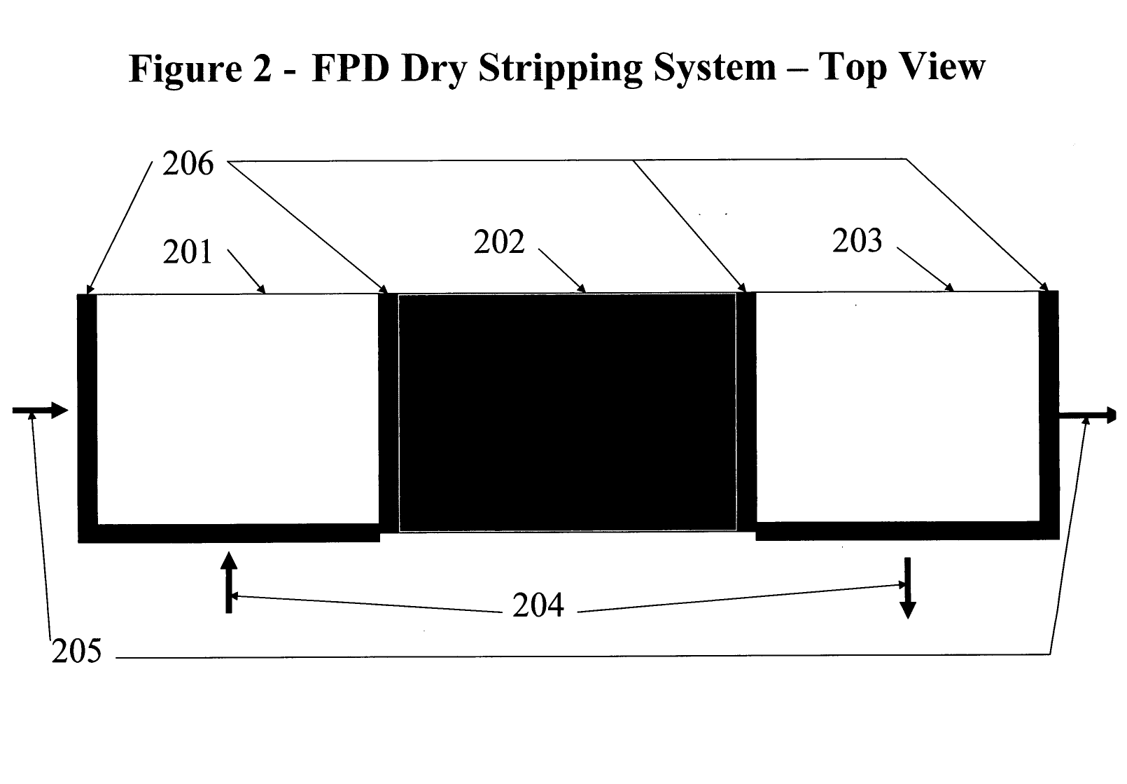

The embodiment shown in FIG. 2 is similar to that of FIG. 1. Substrates can be loaded into and unloaded from load locks 201, 203 either in an in-line manner, as indicated by arrows 205, or in a lateral or side direction, as indicated by arrows 204. Processing chamber 202 and the load locks 201, 203 are in-line and separated from each other and from the surrounding atmosphere by vacuum valves 206.

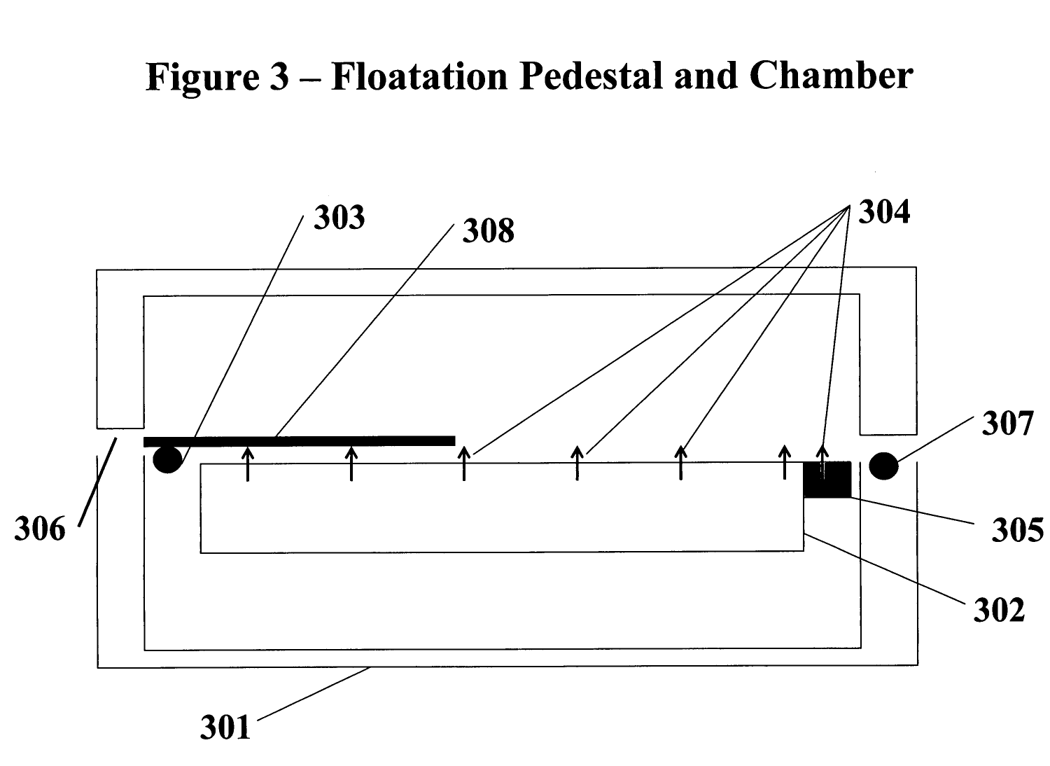

FIG. 3 shows a load lock chamber or processing chamber 301 in which a pedestal 302 is provided with a gas supply that produces outflow of gas on its upper surface, as shown by arrows 304. This gas levitates a substrate 308 and allows it to move easily into and out of the chamber. The outflow of gas also occurs from the tracks 305 which can be used to bridge the gap between the pedestal and the walls of the chamber. Rollers 303 and/or 307 can also be used to support the substrate during movement. Roller 303 is positioned between the wall of the chamber and the pedestal to support the substrate as it passes between them, and roller 307 is positioned inside the opening in the chamber wall to reduce friction as the substrate passes into or out of the chamber.

The pedestals in all three chambers have small holes and/or grooves in their upper surfaces through which the gas can flow to cause the substrates to float above the pedestal surface as needed. Such floatation is done during substrate movement, both under atmospheric pressure conditions and under vacuum, and during substrate heat-up and/or cool-down. For processes which require the substrates to be at an elevated temperature, the input load lock can have a heated pedestal to pre-heat the substrate in a controlled manner, and the the output load lock can have a cooled pedestal for cooling the substrates down after processing.

To maximize throughput of the system, while one substrate is being processed in the processing chambers, the input and output load locks are being cycled to atmosphere and back to vacuum. This permits new substrates to be brought in to the input load lock and processed substrates to be unloaded from the output load lock, while another substrate is being processed. In this way the total process time for a substrate is equal only to the sum of the processing time and the time for moving it into the process chamber from the input load lock. This is because the processed substrate is being removed through the exit lock at the same time a new substrate is being introduced into the inlet load lock and the one ahead of it is moving into the processing chamber.

At the outset of processing, the substrates are moved into the input load lock from a staging platform (not shown) which can either be in-line with the system or to one side of the system, as shown in FIG. 2. The staging platform can be a floatation pedestal as in the load lock and process chambers, or it can utilize any other suitable means such as a set of rollers on which the substrate can be rolled into the input load lock chamber. The substrate can be moved by any mechanism including roller motion or a “pusher” mechanism from the staging platform into the load lock. In the event the substrate is to be heated prior to processing, it is floated on a cushion of gas as it is moved in and kept floating as the input valve door is closed and the load lock chamber is being pumped down to vacuum transfer pressure. The substrate is then floated again just prior to being moved from the input load lock to the processing chamber. In the event that the system has more than one processing chamber, the substrate is floated as it is moved into the first of chamber in the group.

The vacuum door between the input load lock and the processing chamber is opened, as is the door between the processing chamber and the output load lock. If there is more than one in-line processing chamber, the doors between those chambers are opened, too.

The gas for floatation is delivered through all pedestals, both in the processing chambers and load locks. The required rate of gas flow for substrate floatation is very modest under vacuum conditions, and there is easily sufficient pumping in all chambers to maintain an adequately low pressure for rapid transition to the processing mode. All substrates in the system under vacuum are then moved at approximately the same time. The leading substrate can be moved slightly ahead of or sooner than the trailing substrate—in sequence for multiple processing chambers—so that adequate spacing between substrates is maintained. Once substrate movement is completed, the vacuum doors between the chambers are closed and the processing can commence on the substrate just loaded into the processing chamber. Just prior to the beginning of the processing, the gas for floatation in the processing chamber is stopped so that the substrate is not floating during processing.

In the event that there is more than one sequential processing chambers in-line, any substrate entering a processing chamber with a temperature different than that of the preceding chamber can continue to be floated until it gradually reaches the proper processing temperature. In the output load lock, the newly received substrate is floated in the event it needs to cool down from an elevated processing temperature. When the substrate reaches the pedestal temperature, gas for floatation can be stopped. Once the output load lock has been vented to atmospheric pressure the door between it and the exit stage can be opened and the substrate moved out of the vacuum system.

The substrates are supported on the pedestals by a cushion of gas which is supplied by the pedestals. The flow of such gas can be in the range from a few tens of standard cubic centimeters of gas per minute to tens of standard liters per minute. Generally, the flow required will depend on the ambient pressure in the chamber and how high above the pedestal surface the substrate should be levitated. For atmosphere pressure conditions, gas flows can be in a higher range, from hundreds of standard cubic centimeters per minute to ten liters per minute, whereas for near vacuum conditions for movement between the load lock and process chambers, the flows are in a lower range, between tens of standard cc per minute and several standard liters per minute.

As noted above, the substrates can be supported by rollers located in the openings in the chamber walls and/or in the spaces between the inner walls of the chambers and the pedestals in the chambers as they pass from the staging pedestal to the input load lock, or from the input load lock to process chamber, or from the process chamber to output load lock. The substrate can also be supported by air-tracks as it passes into or out of any chamber. The air track is controlled so that it operates only when the substrate is moving and may need to be supported by it.

The heat-up and cool-down times for a substrate do not add to the total process time. This is true for heat-up because the substrates are heated up in the input load lock while that load lock is being pumped down from atmospheric pressure to the pressure at which substrate transfer takes place. It is true for cool-down because the substrates are cooled at the same time as the output load lock is being vented back up to atmospheric pressure. The heat-up and cool-down of the substrates should not be done in a manner which is too non-uniform or too rapid if damage to the sensitive components on the substrate is to be avoided.

To accomplish heat-up in a uniform and controlled manner the flows of gas for substrate floatation must be controlled to keep the rate of heating or cooling of the substrate within allowable limits. After receiving the substrate in the input load lock, as the pressure in the chamber drops, the gas that floats the substrate is reduced in flow so that the gap between the substrate and the heated pedestal gradually decreases. This is done in order to increase the heat conductivity of the gap between pedestal and substrate. When the substrate first enters this chamber it is cold, and depending on the temperature differential, the heat transfer rate from the pedestal to the substrate is highest for a given pressure and gap between substrate and pedestal. At this time the gap should be maximized since the conductivity of the gas at the high pressure is greatest and the temperature differential between substrate and pedestal is also a maximum.

As the substrate heats-up and the pressure in the chamber drops the gap should be gradually decreased so that the rate of temperature increase of the substrate remains high enough to accomplish the heat-up in the required time. Since the gap depends directly on the flow rate of the gas and inversely on the chamber pressure (the pressure in the gap is only slightly greater than that in the chamber since it takes only a small pressure differential to levitate the substrate) the proper flow can be set to achieve the desired gap and the desired thermal conductivity and heat conduction of the gap. Roughly speaking, the rate of heat conduction should be kept approximately constant at nearly the maximum allowable rate so that the rate of increase of the substrate temperature is adequate to accomplish heat-up or cool down in less time than that needed for pumpdown of the input load lock or vent-up of the output load lock. In this way the heat-up and cool-down do not increase the total process time.

Substrates can be moved between chambers in vacuum, from pedestal to pedestal, by means of mechanical pushing elements or rollers or other suitable means. Such means need to keep the substrate oriented properly and move it quickly from one chamber to another. The support mechanism for the substrate can include stops which move into place to prevent the substrate from moving too far and to keep it in the proper orientation. The substrate is either supported by the cushion of gas from the pedestal or by the rollers or by the cushion of gas from the tracks.

It is apparent from the foregoing that a new and improved substrate handling system and process for manufacturing large substrates has been provided. While only certain presently preferred embodiments have been described in detail, as will be apparent to those familiar with the art, certain changes and modifications can be made without departing from the scope of the invention as defined by the following claims.

1. Apparatus for moving large rectangular substrates from atmosphere into a sub-atmospheric processing chamber for etching or photoresist stripping having a narrow spacing between showerhead and pedestal, where the processing chamber requires the substrate to be at a process temperature different from ambient, comprising:
a pedestal for supporting the substrate during processing having a plurality of small holes in its upper surface for providing gas from a controlled source to levitate the substrate as it moves onto or off of the pedestal,
two load lock chambers with vacuum doors, both to the processing chamber and to the substrate supply or receiving stations, one chamber for supplying substrates to the processing chamber at reduced pressure and another chamber for receiving substrates at a reduced pressure following processing,
a heater, within the supplying load lock chamber, that heats the substrate to a desired temperature at a controlled rate as the substrate is supported at the proper distance from the heater, and
a cooling surface for the substrate within the receiving load lock that removes heat from the substrate in a controlled manner following the processing so as to leave the substrate much nearer ambient temperature.

2. A process for moving large rectangular substrates from atmosphere into a sub-atmospheric processing chamber for etching or photoresist stripping where there is only a narrow gap between showerhead and pedestal, and where said processing chamber requires the substrate to be at a process temperature different from ambient, comprising the steps of:
moving the substrate to be processed into a supplying load lock chamber where it is heated to become much closer to the processing temperature as it is kept at a controlled distance from the heater surface within the load lock,
the substrate being more frequently moved into the load lock chamber as a preceding substrate is being processed in the adjacent processing chamber,
moving the substrate from the supplying load lock onto the pedestal in the processing chamber substantially at the same time as the previously processed substrate is moved into a receiving load lock chamber, with both being supported all or in part by the flow of gas from the pedestal beneath the substrate,
the substrate arriving into the processing chamber at a temperature much closer to the desired temperature for processing, and
cooling the substrate within the receiving load lock to removes heat from the substrate in a controlled manner following the processing so as to leave the substrate much nearer ambient temperature.

3. The process of claim 2 wherein the substrate is cooled by bringing the substrate into contact with a cooling surface in the receiving load lock.

4. A process for moving large rectangular substrates from atmosphere into a sub-atmospheric processing chamber for etching or photoresist stripping where there is only a narrow gap between showerhead and pedestal, and where said processing chamber requires the substrate to be at a process temperature different from ambient, comprising the steps of:
moving the substrate to be processed into a supplying load lock chamber where it is heated to become much closer to the processing temperature as it is kept at a controlled distance from the heater surface within the load lock,
maintaining the supplying load lock chamber at a transfer pressure that is below the processing pressure as the substrate is being heated,
moving the substrate from the supplying load lock onto the pedestal in the processing chamber, with the substrate being supported all or in part by the flow of gas from the pedestal beneath the substrate,
the substrate arriving into the processing chamber at a temperature much closer to the desired temperature for processing, and
moving the substrate into a separate receiving load lock, with the substrate being supported all or in part by the flow of gas from the pedestal beneath the substrate.

5. The process of claim 4 wherein the substrate is moved into the processing chamber substantially at the same time as a previously processed substrate is moved into the receiving load lock chamber.

6. The process of claim 4 wherein the substrate it is cooled down in the receiving load lock chamber as that chamber is being repressurized to atmospheric pressure.
